(19) United States
(12) Patent Application Publication
(10) Pub. No.: US 2010/0237360 A1
(43) Pub. Date: Sep. 23, 2010

(54) LIGHT EMITTING DIODE AND BACK LIGHT MODULE THEREOF

(76) Inventors: Chih-Chiang Kao, Kaohsiung City (TW); Meng-Sung Chou, Taipei County (TW); Hsu-Tsu Wang, Taipei County (TW); Chen-Hsiu Lin, Taipei Hsien (TW); Chia-Hao Wu, Taipei City (TW)

Correspondence Address: KILE GOEKJIAN REED & MCMANUS, 1200 NEW HAMPSHIRE AVE, NW, SUITE 570, WASHINGTON, DC, 20036, US

(21) Appl. No.: 12/503,852

(22) Filed: Jul. 16, 2009

(30) Foreign Application Priority Data
Mar. 19, 2009 (CN) 200910038102.1

(51) Int. Cl. H01L 33/00

(52) U.S. Cl. 257/88; 257/98; 257/99; 257/E33.066; 257/E33.068; 257/E33.061

(57) ABSTRACT

A light emitting diode (LED) includes an LED chip, a substrate structure, a fluorescence layer, and a lens. The substrate structure includes a cavity. The fluorescence layer covers on the LED chip and is configured in the cavity and covering the LED chip. The lens is installed on the substrate structure. The lens includes a curved lateral wall, a plane at the top, and a conical concave portion at the top center.

### BACKGROUND OF THE INVENTION

1. Field of the Invention

The present invention relates to a light emitting diode and a back light module thereof, and more particularly, to a light emitting diode with a lens in order to have laterally distributed light and a back light module thereof.

2. Description of the Prior Art

Thanks to the cold lighting, lower power consumption, high durability, fast response time, small dimension, shock proof, easiness for mass production, and highly applicability, Light emitting diode (LED) has been widely used in many fields in recent years. For different applications, the light pattern and the view angle of LEDs are both major considerations in design. Especially for the display and projection applications, the spacing between two adjacent LEDs, and the distance between the LEDs and the projected plane must also be fine tuned to have uniform luminance on the projected plane.

Typically, LEDs emit light in a Lambertian pattern with divergence angle of approximately 120 degree and has the maximum luminous intensity along the normal direction that is exactly why a back light module may have dotted-like distribution at the projected plane when the distance between the projected plane and the LEDs is reduced or the spacing between two adjacent LEDs is enlarged. As a result, when such LEDs are to make the light source of a back light module, the spacing between the LEDs must be limited to within a certain distance in order to have luminance and light uniformity as required. Increasing number of LEDs that adds to the cost is inevitable.

To solve the aforementioned issue, most back light modules mainly adopt LED with full lateral distribution. All of such disclosures add a lens above the LED package with a reflective layer plated at the top center of the lens. The curvature of the lens refracts the emitted light from LED chip to a large-angle direction, which is nearly parallel to the horizon, and the reflective layer on lens eliminates the emission toward normal direction of LED. Such LED has extremely weak light emitted at the normal direction. This makes backlight module not easy to have excellent performance for brightness when applying this kind of LED to direct type backlight module.

### SUMMARY OF THE INVENTION

The present invention provides a light emitting diode (LED). The light emitting diode includes a light emitting diode chip, a substrate structure, a fluorescence layer, and a lens configured on the substrate structure including a curved lateral wall, a plane at the top, and a conical concave portion at the top center.

The present invention further provides a back light module that includes a reflective sheet, a diffuser plate configured above the reflective sheet, and a plurality of light emitting diodes mounted between the reflective sheet and the diffuser plate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration of a first embodiment of a light emitting diode according to the present invention.

FIG. 2 is an illustration of a second embodiment of the light emitting diode according to the present invention.

FIG. 3 is an illustration of a lens according to the present invention.

FIG. 4 is an illustration of a first substrate plate of the first embodiment.

FIG. 5 is an illustration of a second substrate plate of the first embodiment.

FIG. 6 is an illustration of a third substrate plate of the first embodiment.

FIG. 7 is an illustration of the first embodiment of the light emitting diode with the lens.

FIG. 8 is an illustration of the bottom view of the first embodiment of the light emitting diode.

FIG. 9 is an illustration of a chart of the light intensity to the angle of the presently disclosed light emitting diode C and a light emitting diode D of the prior art.

FIG. 10 shows the planar luminance distribution curves of the presently disclosed light emitting diode C and a light emitting diode D of the prior art.

FIG. 11 is an illustration of a back light module according to the present invention.

### DETAILED DESCRIPTION

Certain terms are used throughout the following description and claims to refer to particular system components. As one skilled in the art will appreciate, manufacturers may refer to a component by different names. The following description and claims distinguish components not by the difference of names but by the difference of functions of the components. In the following discussion and in the claims, the terms “include” and “comprise” are used in an open-ended fashion. Also, the term “couple” is intended to mean either an indirect or direct electrical connection.

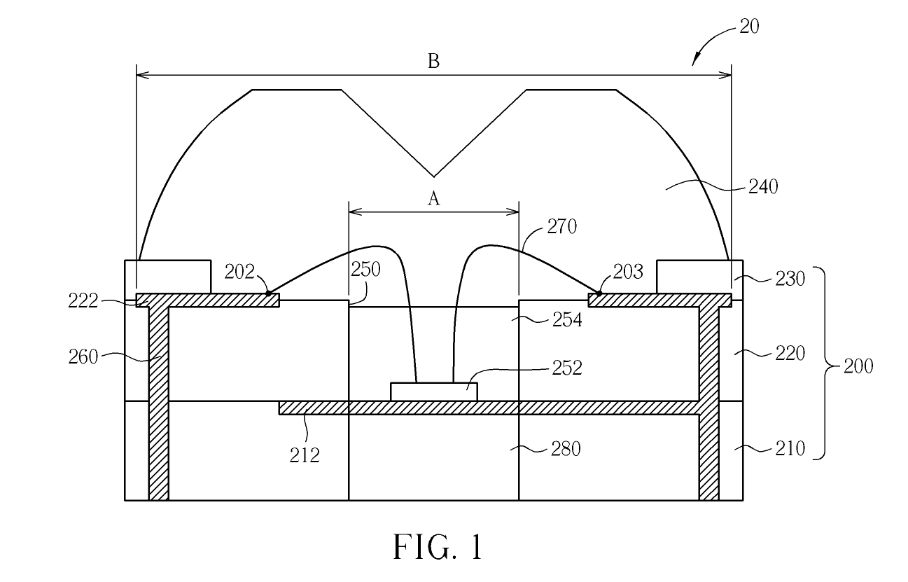

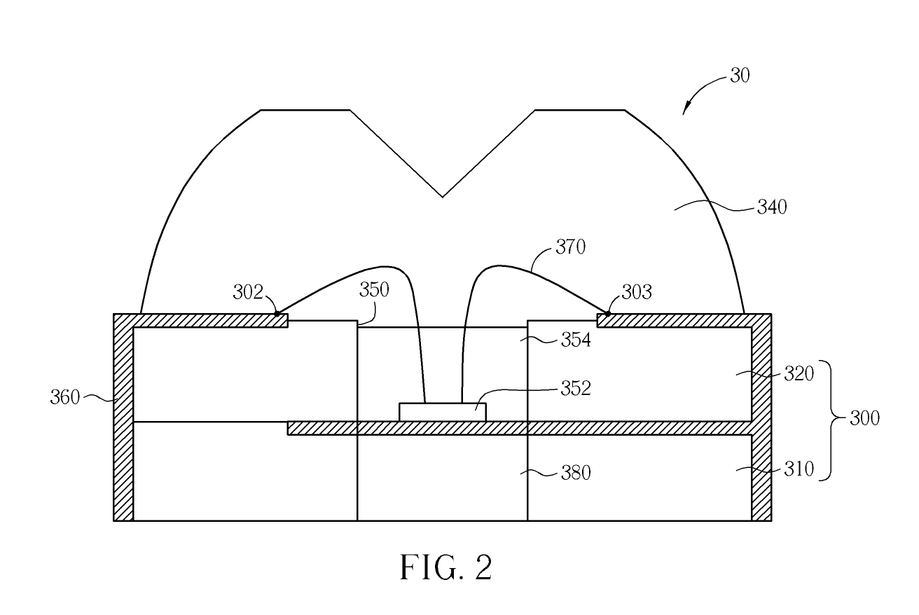

Please refer to FIG. 1 and FIG. 2. FIG. 1 is an illustration of a first embodiment of a light emitting diode 20 according to the present invention, and FIG. 2 is an illustration of a second embodiment of a light emitting diode 30 according to the present invention. The light emitting diode 20(30) include a substrate structure 200(300), a light emitting diode chip 252(352), a fluorescence layer 254(354), and a lens 240(340). The substrate structure 200(300) includes a cavity 250(350) that can contain the light emitting diode chip 252(352), with the fluorescence layer 254(354) configured therein and covering the light emitting diode chip 252(352). The fluorescence layer 254(354) can transform part of the radiation emitted from the chip 252(352) into radiation with other wavelength, and the cavity design can enhance color uniformity of the light emitting diode 20(30). The lens 240(340) is configured on the substrate structure 200(300) to adjust the radiation pattern emitted by the light emitting diode chip 252(352). The substrate structure 200(300) further includes at least a conductive pad 202,203(302,303) for providing voltage for the light emitting diode chip 252(352).

In this embodiment, the substrate structure 200(300) is preferred a stacked multilayer structure that is composed of at least a first substrate 210(310) and a second substrate 220(320) overlapping the first substrate 210(310), which in other words, the substrate structure 200, for exemplary purpose, can also includes a third substrate 230 that further overlaps the second substrate 220.

The substrate structure 200(300) further includes a multi-layer metallic structure besides the stacked multilayer structure.

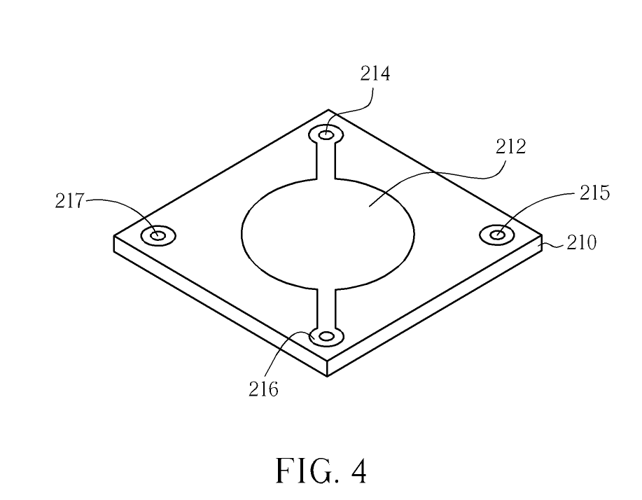

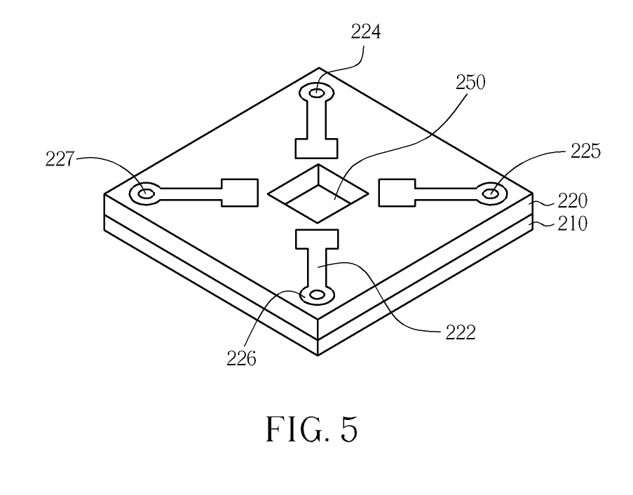

The conductive pads 202,203(302,303) form a part of the multi-layer metallic structure. Taking FIG. 1 for example, the multi-layer metallic structure includes at least a second metallic layer 222 that contains the positive and negative conductive pads 202,203. The multi-layer metallic structure also includes a first metallic layer 212 locating between the first substrate 210 and the second substrate 220, and functioning as a heat dissipating structure (incorporating with its generic electric conducting function) for dissipating heat generated from light emitting diode chip 252. Such multi-layer metallic structure deploys its two metallic layers 212,222 into the stacked multi-layer substrate structure via coating, plating, printing, metallic thin film snapping, or lead framing. A conductor 260 can further connect the two metallic layers 212,222 monolithically such as the lead frame 360 shown in FIG. 2 or by setting up at least two through holes between each layer of the multi-layer substrate stacking structure, such as the first holes 214,215 shown in FIG. 4 or the second holes 224,225 shown in FIG. 5, which are filled with a metallic element like the conductor 260(360) shown in FIG. 1 (FIG. 2). Since the through holes provide electrical connection between the first metallic layer 212 and the second metallic layer 222, they are also called conductive holes, while the metallic element can be filled therein by plating, or instilling with metal liquid or metal glue.

The light emitting diode chip 252(352) is electrically connected to the substrate structure 200(300) by connecting at least a conductive wire 270(370) to the light emitting diode chip 252(352) and the conductive pads 202,203(302,303). In addition, the lead frame 360, the first metallic layer 212, and the second metallic layer 222 belonged to the multi-layer metallic structure can be made of Cu—Ni—Ag alloy or Cu—Ni—Au alloy, and the conductor 260 can be made of silver (Ag).

The stacked multi-layer structure of the substrate structure 200(300), i.e., the first substrate 210(310), the second substrate 220(320), and the third substrate 230, is composed by a heat plate, a conductive plate, a Printed circuit board (PCB), or a ceramic plate. In other words, the stacked multi-layer structure of the substrate structure 200(300) can be made of silicon, ceramic, metal, or mixture of the above.

The stacked multi-layer structure of the substrate structure 200(300) further includes a heat sink 280(380) where the light emitting diode chip 252(352) is mounted thereon. The heat sink 280(380) is made of copper (Cu) or silver (Ag) so as to dissipate heat generated by the light emitting diode chip 252(352). In the embodiment of the present invention, the heat sink 280(380) can also be formed as part of the first substrate 210(310).

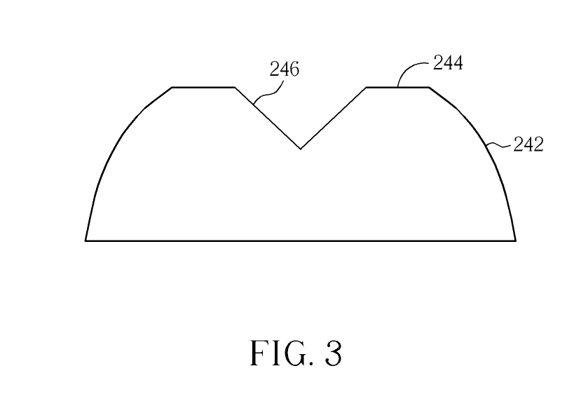

Please refer to FIG. 3. The lens 240 of this embodiment according to the present invention features a unique shape including a curved lateral wall 242, a plane 244 at the top, and a conical concave portion 246 at the top center. The lens 240 is capable of adjusting the radiation pattern of the light emitting diode 20(30) to a wide-angle distributed pattern. Please also refer to FIG. 1 and FIG. 2. The cavity 250(350) in the substrate structure 200(300) of the light emitting diode 20(30) has a width A smaller than one third of the diameter B of the lens 240(340) such that the light emitting diode chip 252(352) acts as a point light source to the lens when placed in the cavity 250(350).

Additionally, the multi-layer metallic structure can further include a third metallic layer located at the bottom of the light emitting diode 20 in this embodiment to form a driving circuit, which is provided with at least a corresponding positive and negative voltages and not shown in the figures, and the third metallic layer further electrically connects to the positive and negative conductive pads 202,203 so that the light emitting diode chip 252 can be driven to emit radiation. Please refer to FIG. 4 to FIG. 7, and FIG. 1. When the first substrate 210 is overlapped by the second substrate 220, the first holes 214,215,216,217 together with the corresponding second holes 224,225,226,227 are filled with the metallic element and form electrical connection with corresponding driving circuit formed by the third metallic layer. Taking a single LED chip as an example, the positive pad of the light emitting diode chip 252 can be connected to the corresponding positive pad of the driving circuit. That is to say that the conductive wire 270 can connect the conductive pad 202 and the light emitting diode chip 252, and the conductive pad 202 can connect the corresponding positive pad of the driving circuit via the metal element filled in one of the first holes 215,217 and corresponding one of the second holes 225,227. Similarly, the negative pad of the light emitting diode chip 252 can be connected to the conductive pad 203 via the conductive wire 270 and the conductive pad 203 can be connected to the corresponding negative pad of the driving circuit via the metallic element filled in one of the first holes 214,216 and corresponding one of the second holes 224,226. The positive pad and the negative pad of the light emitting diode chip 252 can also be connected to the other conductive pads 202,203 via the conductive wires 270 as the opposite way as the above.

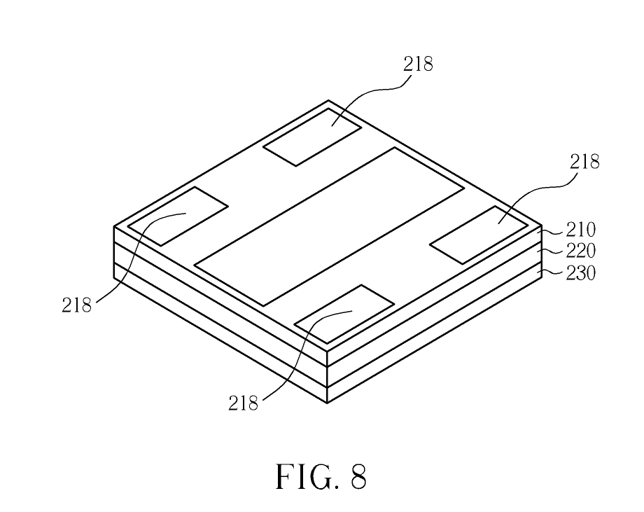

Please refer to FIG. 8, which is an illustration of the bottom view of the first substrate 210 of the first embodiment of the light emitting diode 20 according to the present invention. The first substrate 210 of the light emitting diode 20 includes a third metallic layer at the bottom and includes a plurality of metallic pads 218 as a driving circuit. At least two of the metallic pads 218 connect to the positive pad and the negative pad of the light emitting diode chip 252 respectively, and can be provided with a positive voltage and a negative voltage for driving the light emitting diode chip 252 to emit radiation. Additionally, an alternative is applicable in the light emitting diode 20 of the invention to deploy a plurality of light emitting diode chips 252 in the cavity 250, with these chips electrically connecting to one another in a serial or parallel way. Furthermore, the serial or parallel connection of the chips can be achieved by the way the metallic pads 218 connect to the positive pad and the negative pad of the driving circuit, and the way the conductive wires 270 connect to the conductive pads 202,203. For two chips as an example, The metallic pads 218 connecting to an outer power source provide only one pair of positive/negative pads and the two chips electrically connect to the conductive pads 202,203 via the conductive wires 270 respectively for parallel connection; a conductive wire connects the positive pad of one chip and the negative pad of another chip for serial connection. (Notes: The serial connection also can be achieved by wire bonding on substrate; it is not necessary to wire bonding between chip pads.) The positive pad and the negative pad mentioned above can be altered accordingly when discussing about the connection method.

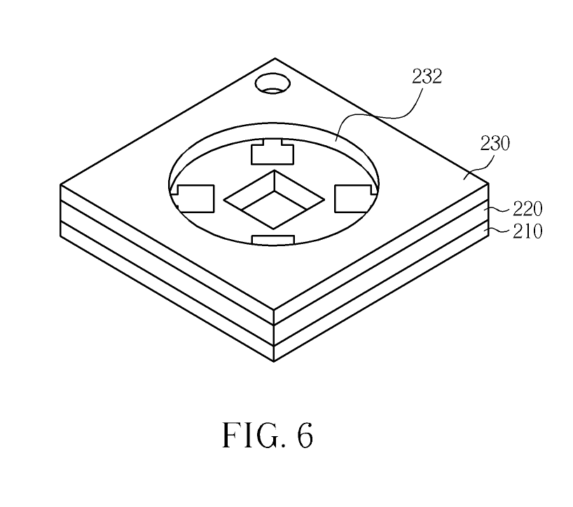

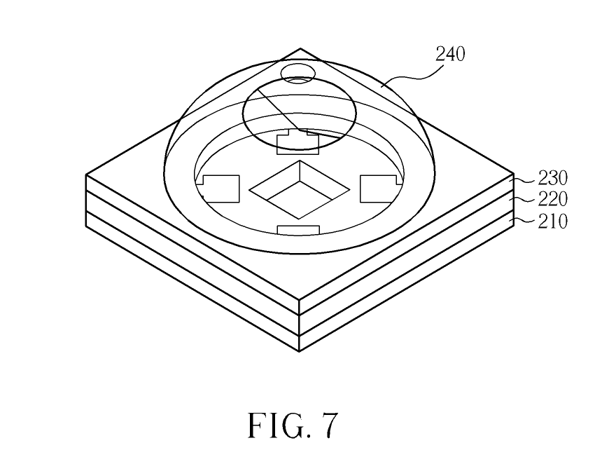

Please refer to FIG. 1 and also refer to FIG. 4 to FIG. 7. The first substrate 210 includes at least a first metallic layer 212 having a plurality of first holes 214,215,216,217. FIG. 5 shows that the second substrate 220 includes at least a second metallic layer 222 having a plurality of second holes 224,225,226,227. To electrically connecting the light emitting diode chip 252 to the outer power source, the first holes 214,215,216,217 and the second holes 224,225,226,227 are respectively overlapped with each other and are filled with metallic element to form a conductor 260 respectively (or conductive hole) penetrating through the first substrate 210 and the second substrate 220. The positive/negative pads 202,203 can then electrically connect to the outer power source via the conductors 260. The conductors 260 in the second holes 224,225 further electrically connect the first metallic layer 212 to the second metallic layer 222. FIG. 6 shows that the third substrate 230 caps the second substrate 220 and has a containing space such that the conductive wires 270 connecting the light emitting diode chip 252 and the second metallic layer 222 can be protected. FIG. 7 shows that the lens 240 is configured above the third substrate 230 for adjusting the radiation pattern of the light emitting diode 20(30).

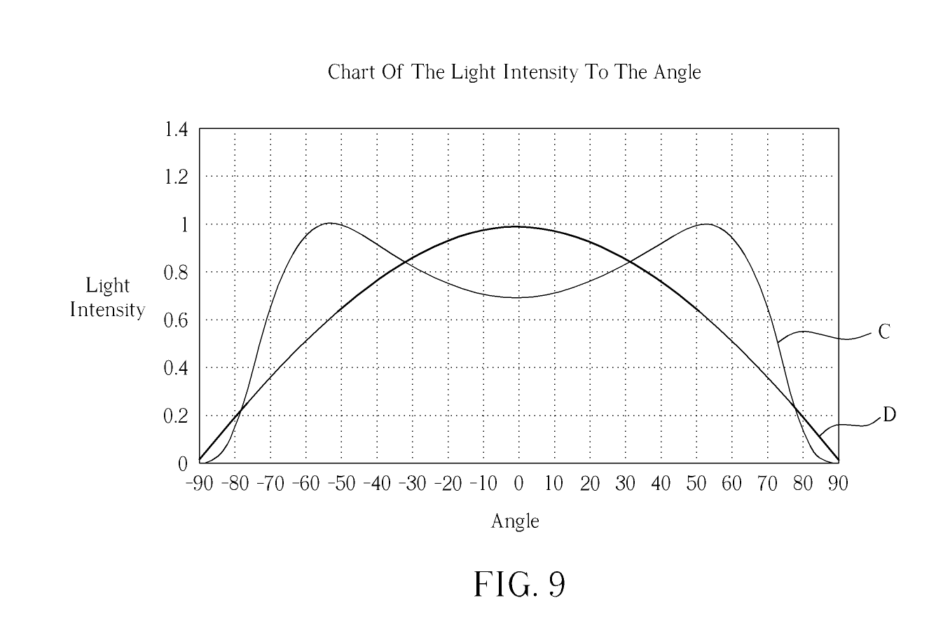

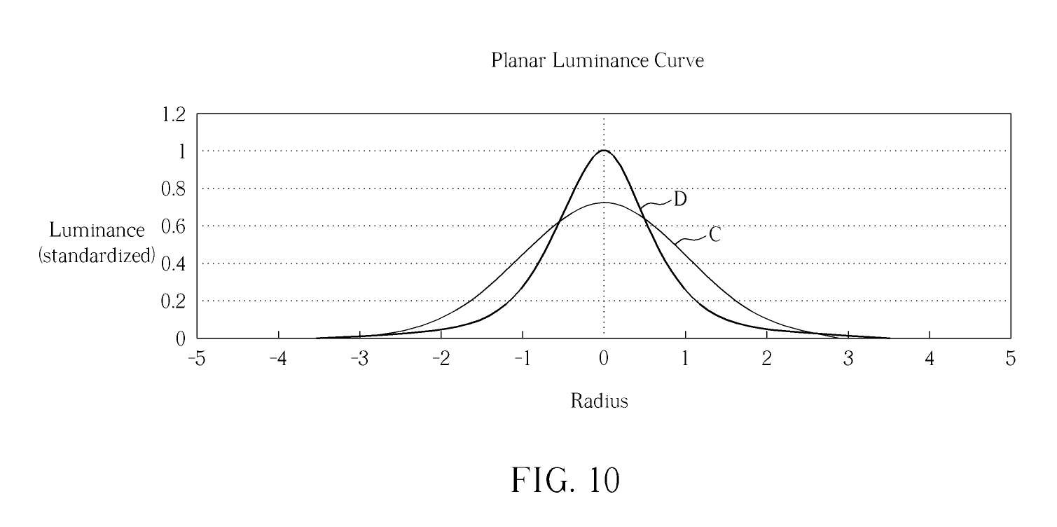

The lens 240(340) is adopted in the invention to improve the radiation pattern of the light emitting diode 20(30). The light emitting diode 20(30) can therefore have wing-shape radiation pattern by configuring the light emitting diode chip 252(352) in the cavity 250(350), which has a specific dimension in proportion to the lens 240(340). The light emitting diode 20(30) can have such wing-shape radiation pattern that the luminous intensity of the light emitted toward the central direction is slightly smaller than that of the light emitted toward the wide-angle direction. The luminous intensity of the area between two adjacent light emitting diodes 20(30) is less deviated from the luminous intensity of the area of each normal direction of the light emitting diode 20(30) even when two adjacent light emitting diodes 20(30) have greater spacing or get more close to the projected plane. On condition of providing uniform luminance, the light emitting diodes 20(30) disclosed in the present invention can be deployed with larger spacing or be deployed as light source in a direct-type back light module that can have shorter distance between the back light module and the thin film transistor/LCD module. Additionally, the light emitting diode 20(30) disclosed in the invention emits light with wavelength ranging between 300 nm and 700 nm. Please refer to FIG. 9 and FIG. 10. FIG. 9 is an illustration of a chart of the light intensity to the angle of the presently disclosed light emitting diode C and a light emitting diode D of the prior art. FIG. 10 shows the planar luminance distribution curves of the presently disclosed light emitting diode C and a light emitting diode D of the prior art. FIG. 9 shows that the light emitting diode D of the prior art provides a light pattern where the maximum light intensity happens at the normal direction, with decreasing light intensity when deviating from the normal direction. The light emitting diode C of the present invention, however, has a light pattern that the light with maximum luminous intensity lies between an angular range of 40 degree to 70 degree from the normal direction, while the luminous intensity of the light in the normal direction is roughly between 40% and 70% of the light with maximum luminous intensity. FIG. 10 shows that the radius of the light pattern of effective intensity of a prior art light emitting diode D is smaller than that of the presently disclosed light emitting diode C. From the above illustrations, the light emitting diode 20(30) of the invention effectively changes the light pattern of the light emitting diode chip 252(352) to a wing-shape light pattern and therefore has larger luminous angle range and larger luminous radius.

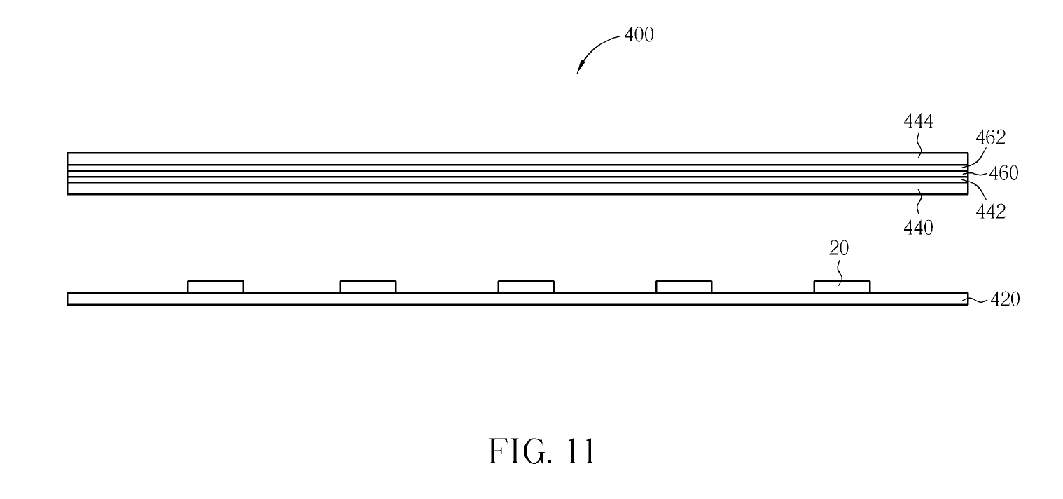

Please refer to FIG. 11, which is an illustration of a back light module 400 applying the light emitting diode 20(30) of the present invention. The back light module 400 includes a reflective sheet 420, a diffuser plate 440, and a plurality of light emitting diodes 20 (or 30). The diffuser plate 440 is configured above the reflective sheet 420, the plurality of light emitting diodes 20 are configured between the reflective plate 420 and the diffuser plate 440. Additionally, a first diffuser film 442, a first brightness enhancement film (BEF) 460, a second BEF 462, and a second diffuser film 444 can also be configured above the diffuser plate 440. The light emitted by the light emitting diodes 20 is diffused to a panel, which is not shown in the figure. The reflective plate 420 reflects the light scattering down back to the diffuser plate 440 for recycling the light. The diffuser films 442,444 further guide the lights transmitted through. Due to the characteristic of the wing-shape light pattern of the light emitting diodes 20 in the back light module 400, each two adjacent light emitting diodes 20 can be deployed in the back light module 440 with spacing ranging between 20 mm and 40 mm, or preferably 25 mm and 29 mm. Additionally, the height to width ratio of the spacing between two adjacent light emitting diodes 20 ranges between 0.5 and 1 such that the quantity of light emitting diodes 20 needed for the back light module 400 can be substantially reduced, while still meeting the requirement of the luminous intensity and the luminance uniformity of the back light module 400. The distance H between the light emitting diodes 20 and the diffuser plate 440 can be further reduced due to the laterally distributed light pattern of the light emitting diodes 20. Therefore, the backlight module 400 can have thinner dimension.

The light emitting diode disclosed in the invention uses a lens with specific shape and specially manipulated proportion of the cavity to the lens so that the light pattern of the light emitting diode can be adjusted to be wide-angle distributed. The wire bonding technology to connect the chip with the voltage nodes disclosed in FIG. 1 and FIG. 2 is not the only way to be applied in the present invention. The flip-chip technique that forms at least a bump on the chip to be “flipped” to connect directly to the substrate structure can also be applied in the present invention. In other words, all packaging technique can be applied incorporating the specially designed lens of the present invention. The back light module provided by the invention can use the light emitting diodes with wing-shape light pattern with substantially reduced quantity for further lowering the cost, without compromising the luminous intensity and uniformity as required. Additionally, by applying the light emitting diode of the present invention, the direct-type back light module can have thinner dimension for the market trend. The light emitting diode can further be applied on streetlamps or most light source applications for design flexibility and competitive ability.

Those skilled in the art will readily observe that numerous modifications and alterations of the device and method may be made while retaining the teachings of the invention.

What is claimed is:

1. A light emitting diode (LED) comprising:
a substrate structure having a cavity;
a light emitting diode chip contained in the cavity of the substrate structure;
a fluorescence layer configured in the cavity and covering the light emitting diode chip; and
a lens configured on the substrate structure;
wherein the lens has a curved lateral wall, a plane at the top, and a conical concave portion at the top center.

2. The light emitting diode of claim 1, wherein the edge length of the cavity is smaller than one third of the diameter of the lens.

3. The light emitting diode of claim 1, wherein the substrate structure comprises a first substrate and the light emitting diode chip is mounted on the first substrate.

4. The light emitting diode of claim 3, wherein the first substrate comprises a first metallic layer, and the first metallic layer has at least a first hole.

5. The light emitting diode of claim 4, wherein the first substrate comprises a heat sink and the light emitting diode chip is mounted on the heat sink and the first metallic layer.

6. The light emitting diode of claim 3, wherein the substrate structure further comprises a second substrate, and the first substrate and the second substrate are overlapped each other to form the cavity.

7. The light emitting diode of claim 6, wherein the first substrate comprises a first metallic layer and the second substrate comprises a second metallic layer.

8. The light emitting diode of claim 7, wherein the first metallic layer comprises at least a first hole and the second metallic layer comprises at least a second hole, and at least one first hole overlaps the second hole.

9. The light emitting diode of claim 8 further comprising:
a metallic element filled in the first hole and the second hole for electrically connecting the first metallic layer of the first substrate with the second metallic layer of the second substrate.

10. The light emitting diode of claim 7 further comprising:
at least a conductive wire electrically connecting the light emitting diode chip with the second metallic layer of the second substrate.

11. The light emitting diode of claim 10 further comprising:
a third substrate overlapping on the second substrate;
wherein the third substrate comprises a containing space for containing the conductive wire.

12. The light emitting diode of claim 11, wherein the lens is mounted on the third substrate.

13. The light emitting diode of claim 1, wherein the substrate structure further comprises a lead frame.

14. The light emitting diode of claim 13 further comprising:
at least a conductive wire electrically connecting the light emitting diode chip with the lead frame.

15. The light emitting diode of claim 14, wherein the substrate structure comprises a first substrate and a second substrate, and the first substrate and the second substrate are overlapped with each other to form the cavity.

16. The light emitting diode of claim 15 further comprising:
a third substrate overlapping on the second substrate;
wherein the third substrate comprises a containing space for containing the conductive wire.

17. The light emitting diode of claim 1, wherein a peak intensity output by the light emitting diode occurs within 40 degree to 70 degree off the normal axis and an intensity along the normal axis is between 40% and 70% of the peak intensity.

18. A back light module having a plurality of light emitting diodes according to claim 1, comprising:
a reflective sheet; and
a diffuser plate configured above the reflective sheet;
wherein the plurality of light emitting diodes is configured between the reflective sheet and the diffuser plate, and any two adjacent light emitting diodes distance each other from 20 mm to 40 mm.

19. A back light module having a plurality of light emitting diodes according to claim 1, comprising:
a reflective sheet; and
a diffuser plate configured above the reflective sheet;
wherein the plurality of light emitting diodes is configured between the reflective sheet and the diffuser plate, and any two adjacent light emitting diodes are disposed with the height to width ratio of the spacing between the two adjacent light emitting diodes ranging between 0.5 and 1.
